(19) United States
(12) Patent Application Publication
(10) Pub. No.: US 2026/0182214 A1
(43) Pub. Date: Jun. 25, 2026

(54) DISPLAY APPARATUS

(71) Applicant: LG Display Co., Ltd., Seoul (KR)

(72) Inventors: Bumhee HAN, Gwangju (KR); JiWon KIM, Seoul (KR); MinSeob SONG, Jeonju-si (KR)

(73) Assignee: LG Display Co., Ltd., Seoul (KR)

(21) Appl. No.: 19/373,473

(22) Filed: Oct. 29, 2025

(30) Foreign Application Priority Data
Dec. 24, 2024 (KR) 10-2024-0195981

(51) Int. Cl. H10K 59/80; G06F 3/041; H10K 59/40

(52) U.S. Cl. CPC H10K 59/873; G06F 3/0412; H10K 59/40; G06F 2203/04102

(57) ABSTRACT

A display apparatus includes a substrate including an active area, a first non-active area enclosing the active area, a bending area extending from the first non-active area and configured to be bent, and a second non-active area extending from the bending area, a plurality of light emitting diodes disposed in the active area on the substrate, a touch sensing unit disposed above the plurality of light emitting diodes, a first planarization layer disposed on the touch sensing unit, a first dam disposed in the first non-active area so as to enclose the active area, a second planarization layer disposed on the first dam and the first planarization layer, and a second dam disposed along a boundary of the first non-active area and the bending area, in the first non-active area. Further, the second dam includes a same material on a same layer as the first planarization layer.

### CROSS-REFERENCE TO RELATED APPLICATIONS

This application claims priority to Korean Patent Application No. 10-2024-0195981, filed on Dec. 24, 2024 in the Republic of Korea, the entire disclosure of which is hereby expressly incorporated by reference into the present application.

### BACKGROUND

### Field

The present disclosure relates to a display apparatus, and more particularly, to a display apparatus which minimizes an organic material which planarizes an upper portion of a display apparatus from being excessively applied on a bending area.

### Description of the Related Art

With advent of the current information era, there has been rapid development of a field of a display apparatus which visually expresses electrical information signals and studies and research have continued to improve performances of various display apparatuses, such as a thin-thickness, a light weight, and low power consumption.

A representative display apparatus of such various display apparatuses can include a liquid crystal display apparatus (LCD), a field emission display apparatus (FED), an electro-wetting display apparatus (EWD), and an organic light emitting display apparatus (OLED) among others.

Among such various display apparatuses, an electroluminescent display apparatus is represented by an organic light emitting display apparatus, and the organic light emitting display apparatus is a self-emitting display apparatus that avoids a need for a separate light source, and so is different from a liquid crystal display apparatus that requires a separate light source. Therefore, the electroluminescent display apparatus can be manufactured to have a light weight and a small thickness by not needing the separate light source. Further, since the electroluminescent display apparatus is advantageous not only in terms of power consumption due to the low voltage driving, but also in terms of color implementation, a response speed, a viewing angle, and a contrast ratio (CR), the organic light emitting display apparatus is expected to be utilized in various fields in the future.

### SUMMARY OF THE DISCLOSURE

An object to be achieved by the present disclosure is to provide a display apparatus which minimizes an organic material which planarizes an upper portion of a display apparatus from being excessively applied on a bending area.

Another object to be achieved by the present disclosure is to provide a display apparatus which expands a space for accommodating an excessively applied organic material.

Still another object to be achieved by the present disclosure is to provide a low power display apparatus in which excessive application of an organic material on a bending area is minimized to improve a lifespan, thereby improving the reliability of the display apparatus to reduce power consumption.

Objects of the present disclosure are not limited to the above-mentioned objects, and other objects, which are not mentioned above, can be clearly understood by those skilled in the art from the following descriptions.

According to an aspect of the present disclosure, a display apparatus includes a substrate which includes an active area, a first non-active area enclosing the active area, a bending area extending from the first non-active area to be bent, and a second non-active area extending from the bending area; a plurality of light emitting diodes disposed on the substrate in the active area; a touch sensing unit disposed above the plurality of light emitting diodes; a first planarization layer disposed on the touch sensing unit; a first dam which is disposed in the non-active area so as to enclose the active area; a second planarization layer which is disposed on the first dam and the first planarization layer; and a second dam which is disposed along a boundary of the first non-active area and the bending area, in the first non-active area, in which the second dam is formed with the same material on the same layer as the first planarization layer.

According to another aspect of the present disclosure, a display apparatus includes: a substrate which includes an active area in which a plurality of sub pixels is disposed, a first non-active area enclosing the active area, and a bending area extending from the first non-active area to be bent; a plurality of light emitting diodes which is disposed in each of the plurality of sub pixels on the substrate; a touch sensing unit disposed above the plurality of light emitting diodes; a first planarization layer disposed on the touch sensing unit; a first dam which is disposed in the non-active area so as to enclose the active area; a second planarization layer which is disposed on the first dam and the first planarization layer; and a second dam which is disposed along a boundary of the first non-active area and the bending area, in the first non-active area, in which the second dam is disposed on the same layer as the first planarization layer and is formed with the same material as the first planarization layer.

Other detailed matters of the example embodiments are included in the detailed description and the drawings.

In the display apparatus of the present disclosure, excessive application of an organic material on the bending area is minimized to improve the reliability of the display apparatus.

In the display apparatus of the present disclosure, a space for accommodating an excessively applied organic material is expanded to further minimize the excessive application of the organic material.

In the display apparatus according to the present disclosure, excessive application of the organic material on the bending area is minimized to improve the reliability and the lifespan of the display apparatus, thereby implementing a low-power display apparatus with reduced power consumption.

The effects according to the present disclosure are not limited to the contents exemplified above, and other various effects are included in the present disclosure.

### BRIEF DESCRIPTION OF DRAWINGS

The above and other aspects, features and other advantages of the present disclosure will be more clearly understood from the following detailed description taken in conjunction with the accompanying drawings, in which:

FIG. 1A is a plan view of a mother substrate used for a manufacturing method of a display apparatus according to an example embodiment of the present disclosure;

FIG. 1B is an enlarged plan view of an area B of FIG. 1A;

FIG. 1C is a plan view of a display apparatus according to an example embodiment of the present disclosure;

FIG. 1D is an enlarged plan view of an area E of FIG. 1C;

FIG. 2 is a cross-sectional view taken along A-A′ of FIG. 1A;

FIG. 3A is a cross-sectional view taken along C-C′ of FIG. 1B;

FIG. 3B is a cross-sectional view taken along the line F-F′ of FIG. 1D;

FIG. 4A is a cross-sectional view taken along D-D′ of FIG. 1B;

FIG. 4B is a cross-sectional view taken along G-G′ of FIG. 1D;

FIG. 5 is a cross-sectional view taken along H-H′ of FIG. 1D;

FIG. 6 is an enlarged plan view of an area I of FIG. 1A; and

FIG. 7 is a cross-sectional view taken along J-J′ of FIG. 6.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies can be omitted to avoid unnecessarily obscuring the subject matter of the present disclosure. The terms such as ‘including’, ‘having’, ‘consist of’ used herein are generally intended to allow other components to be added unless the terms are used with the term ‘only’. Any references to singular can include plural unless expressly stated otherwise.

Components are interpreted to include an ordinary error range even if not expressly stated.

When the position relation between two parts is described using the terms such as ‘on’, ‘above’, ‘below’, ‘next’, one or more parts can be positioned between the two parts unless the terms are used with the term ‘immediately’or ‘directly’.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated. The term “can” fully encompasses all the meanings and coverages of the term “may.” The term “made of” for an element can fully encompass the meaning of being completely formed of the element, or simply including the element.

The features of various embodiments of the present disclosure can be partially or entirely adhered to or combined with each other and can be interlocked and operated in technically various ways, and the embodiments can be carried out independently of or in association with each other.

Hereinafter, various embodiments of the present disclosure will be described in detail with reference to accompanying drawings.

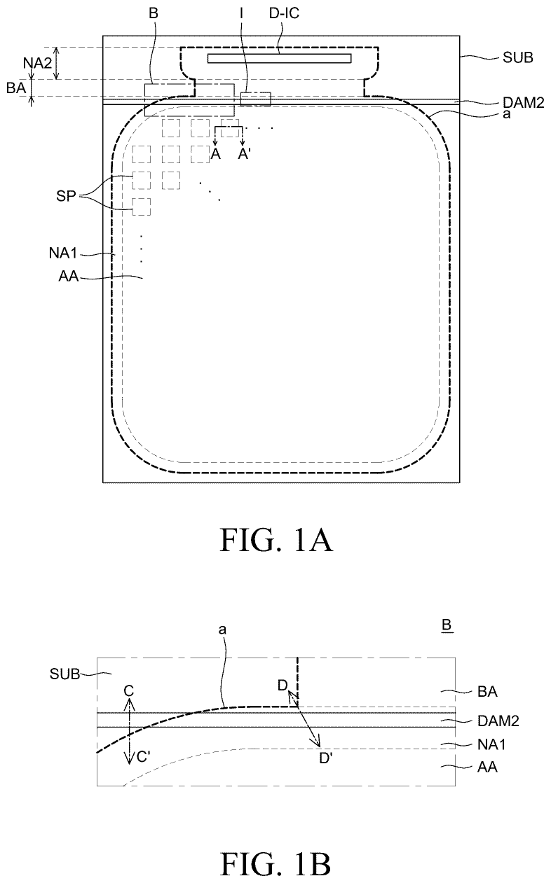

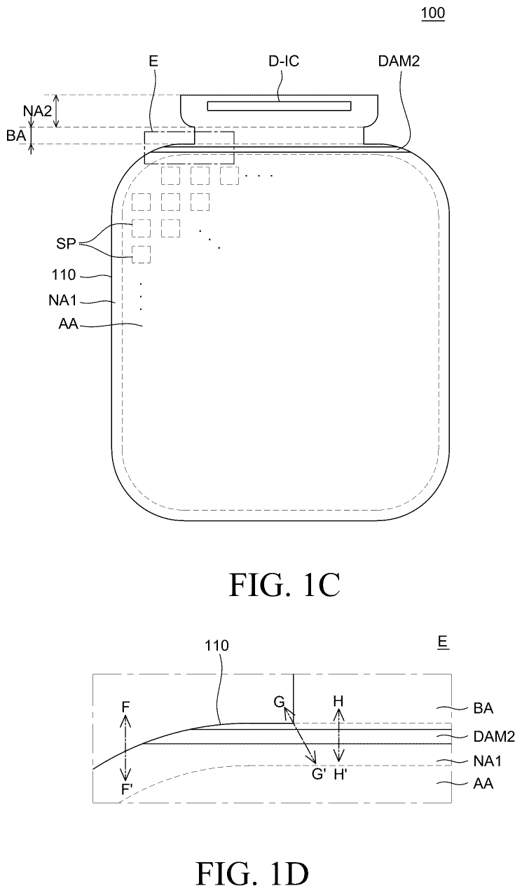

FIG. 1A is a plan view of a mother substrate used for a manufacturing method of a display apparatus according to an example embodiment of the present disclosure. FIG. 1B is an enlarged plan view of an area B of FIG. 1A. FIG. 1C is a plan view of a display apparatus according to an example embodiment of the present disclosure. FIG. 1D is an enlarged plan view of an area E of FIG. 1C. FIG. 1A is a plan view of a mother substrate SUB before a trimming process of a manufacturing method of a display apparatus and FIG. 1C is a plan view of a substrate 110 after the trimming process. All components of each display apparatus according to all embodiments of the present disclosure are operatively coupled and configured.

The display apparatus 100 is an apparatus for displaying images to a user. In the display apparatus 100, a display element which displays images, a driving element which drives the display element, and wiring lines which transmit various signals to the display element and the driving element can be disposed.

The display element can be defined in different manners depending on the type of the display apparatus 100. For example, when the display apparatus 100 is an organic light emitting display apparatus, the display element can be an organic light emitting diode which includes an anode, an organic emission layer, and a cathode. For example, when the display apparatus 100 is a liquid crystal display apparatus, the display element can be a liquid crystal display element. Hereinafter, it is assumed that the display apparatus 100 is an organic light emitting display apparatus, but the display apparatus 100 is not limited to the organic light emitting display apparatus.

Referring to FIGS. 1A to 1D, during the manufacturing process of a display apparatus 100, a step of forming a substrate 110 by performing a trimming process on a mother substrate SUB can be performed. For example, the trimming process can be a cutting process using a laser or a scribing process which directly applies a physical force to the mother substrate SUB using a tool, such as a cutter, but embodiments of the present disclosure are not limited thereto. The trimming process can be performed along a predetermined trimming line a.

The substrate 110 is a component for supporting various components included in the display apparatus 100 and can be formed of an insulating material. In the meantime, the substrate 110 is disposed so as to support components on the lowermost portion of the display apparatus 100 so that the substrate can also be referred to as a lower substrate, but is not limited thereto.

The substrate 110 includes an active area AA and a non-active area.

The active area AA is an area in which images are displayed in the substrate 110. In the active area AA, a plurality of sub pixels SP which configures a plurality of pixels and a driving circuit for driving the plurality of sub pixels SP can be disposed.

The plurality of sub pixels SP is minimum units which configure the active area AA and a display element can be disposed in each of the plurality of sub pixels SP. For example, an organic light emitting diode which includes an anode, an organic emission layer, and a cathode can be disposed in each of the plurality of sub pixels SP, but it is not limited thereto. Further, the driving circuit for driving the plurality of sub pixels SP can include a driving element and a wiring line. For example, the driving circuit can be configured by a thin film transistor, a storage capacitor, a gate line, and a data line, but is not limited thereto.

The non-active area is an area in which no image is displayed. The non-active area can refer to an outer peripheral portion of the substrate 110 which encloses the active area AA. The non-active area can overlap a black matrix. In the non-active area, various wiring lines and circuits for driving an organic light emitting diode in the active area AA are disposed. For example, in the non-active area, a link line which transmits signals to the plurality of sub pixels SP and driving circuits of the active area AA or a driving IC (D-IC) such as a gate driver IC or a data driver IC can be disposed, but it is not limited thereto.

The non-active area includes a first non-active area NA1, a bending area BA, and a second non-active area NA2.

The first non-active area NA1 is an area which encloses the active area AA and extends from the active area AA. The bending area BA can extend from one side of the first non-active area NA1 and can be bent. The second non-active area NA2 is an area which extends from the bending area BA to be disposed below the active area.

In the meantime, referring to FIGS. 1A and 1C, the first non-active area NA1 and the second non-active area NA2 can be disposed on the same plane as the active area AA or disposed to be parallel to the active area AA and maintain a flat state. For example, the first non-active area NA1 can be disposed to be flat on the same plane as the active area AA and the second non-active area NA2 can be disposed below the active area AA to be parallel to the active area AA and be flat, but embodiments of the present disclosure are not limited thereto. Therefore, the active area AA, the first non-active area NA1, and the second non-active area NA2 can be referred to as, for example, non-bending areas, but are not limited thereto.

Referring to FIGS. 1A and 1C, the driving IC D-IC is disposed in the second non-active area NA2. The driving IC D-IC can supply a data signal to the plurality of sub pixels SP. For example, the driving IC D-IC samples and latches the data signal supplied from the timing controller in response to a data timing control signal supplied from the timing controller to convert the data signal into a gamma reference voltage and output the converted gamma reference voltage, but embodiments of the present disclosure are not limited thereto. The driving IC D-IC can output a data signal through the plurality of data lines. For example, in the second non-active area NA2 in which the driving IC D-IC is disposed, a pad unit is disposed and a printed circuit board which is electrically connected to the pad unit is further disposed to supply a signal to the driving IC D-IC, but is not limited thereto.

In the meantime, the driving IC D-IC is disposed on one side of the display panel PN in a chip on panel (COP) manner to be connected to the display panel PN or is disposed in a separate flexible film to be connected to the substrate 110 in a chip on film (COF) manner. In the display apparatus 100 according to the example embodiment of the present disclosure, it is assumed that the driving IC D-IC is disposed in the COP manner, but it is not limited thereto.

At this time, as the substrate 110 is bent, the driving IC D-IC disposed in the second non-active area NA2 can be disposed below the active area AA. For example, the driving IC D-IC and the printed circuit board connected to the pad unit of the substrate 110 can move to the rear surface of the substrate 110 and overlap the active area AA. Therefore, as seen from the top of the substrate 110, circuit elements, such as the driving IC D-IC and the printed circuit board need not be visible. Accordingly, a size of the non-active area which is visible from the top of the substrate 110 is reduced to implement a narrow bezel, but embodiments of the present disclosure are not limited thereto.

A through hole can be disposed in the active area AA. For example, in an area in the active area AA in which a through hole is disposed, an image need not be displayed. The through hole can be a hole which passes through the substrate 110. The through hole can be formed so as to cover a camera or a photo sensor. Therefore, in the display apparatus 100, the through hole is disposed in the active area AA to reduce a bezel area which is a non-active area and maximize the active area AA. As described above, a product with a design which maximizes the active area AA can be aesthetically preferable by maximizing the user's screen immersion.

Referring to FIGS. 1A to 1D, in the first non-active area NA1, a second dam DAM2 is disposed in an area adjacent to the bending area BA. The second dam DAM2 is disposed along a boundary of the first non-active area NA1 and the bending area BA in the first non-active area NA1. The second dam DAM2 can restrict or block a position of the planarization layer so as not to allow the planarization layer which planarizes an upper portion of the component of the display apparatus 100 to overflow to the bending area BA, in the active area AA and the first non-active area NA1.

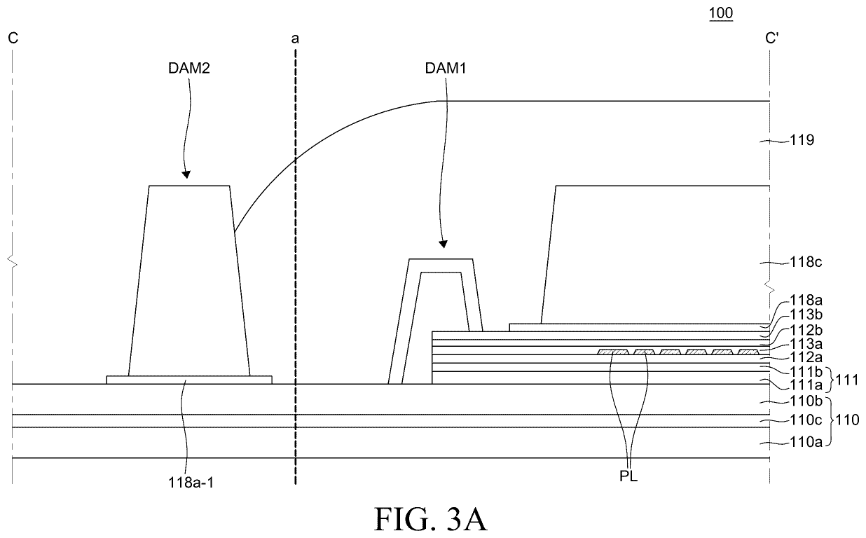

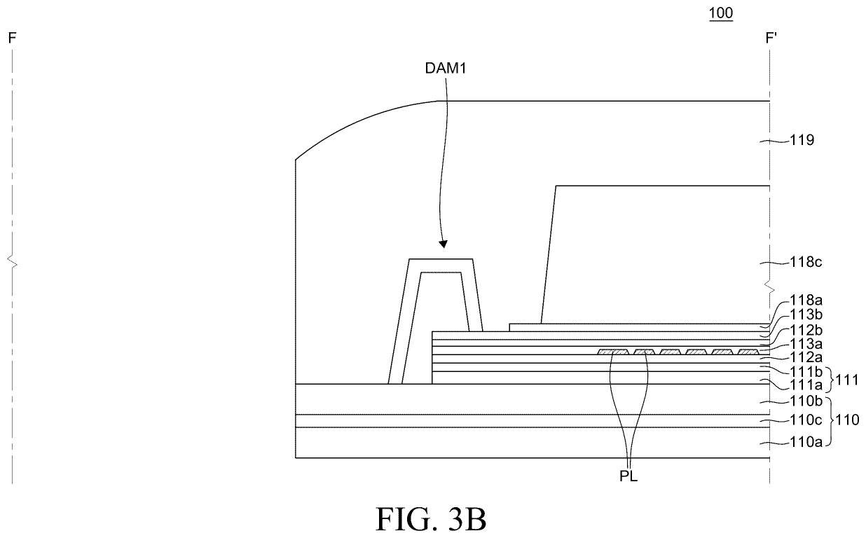

In the meantime, referring to FIG. 1A, the second dam DAM2 can be disposed so as to straightly cross one side of the mother substrate SUB along a boundary of the first non-active area NA1 and the bending area BA, before the trimming process. Referring to FIG. 1C, the second dam DAM2 can be partially removed to be disposed only in an area adjacent to the bending area BA, after the trimming process. The second dam DAM2 after the trimming process, will be described in detail below with reference to FIGS. 3 to 7. As shown in FIGS. 1C and 1D, end portions of the second DAM2 that have been trimmed by the trimming process can have a curvature that follows the predetermined trimming line a.

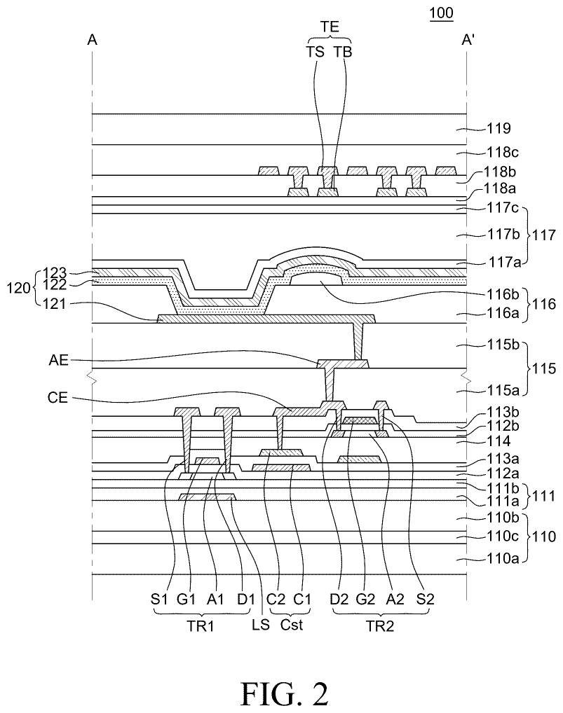

Hereinafter, a cross-sectional structure of the active area AA will be described with reference to FIG. 2 together.

FIG. 2 is a cross-sectional view taken along A-A′ of FIG. 1A. FIG. 2 is a cross-sectional view illustrating a cross-sectional structure of one sub pixel SP disposed in an active area AA according to an example embodiment of the present disclosure.

Referring to FIG. 2, in the display apparatus 100 according to the example embodiment of the present disclosure, in the active area AA, a substrate 110, a light shielding layer LS, a first buffer layer 111, a first thin film transistor TR1, a second thin film transistor TR2, a first gate insulating layer 112a, a first interlayer insulating layer 113a, a second buffer layer 114, a second gate insulating layer 112b, a second interlayer insulating layer 113b, a connection electrode CE, a first planarization layer 115a, a second planarization layer 115b, an auxiliary electrode AE, a bank 116a, a spacer 116b, a light emitting diode 120, an encapsulation unit 117, a touch buffer layer 118a, a touch sensing unit, a touch interlayer insulating layer 118b, a third planarization layer 118c, and a fourth planarization layer 119 are disposed.

The substrate 110 serves to support and protect components of the display apparatus 100 disposed thereabove.

The substrate 110 is a component for supporting various components included in the display apparatus 100 and can be formed of an insulating material. In the meantime, the substrate 110 is disposed so as to support components on the lowermost portion of the display apparatus 100 so that the substrate can also be referred to as a lower substrate, but is not limited thereto.

The substrate 110 can include a first substrate 110a, a second substrate 110b, and an interlayer insulating film 110c. The interlayer insulating film 110c can be disposed between the first substrate 110a and the second substrate 110b. As described above, the substrate 110 is configured by the first substrate 110a, the second substrate 110b, and the interlayer insulating film 110c to suppress the moisture permeation. However, the substrate 110 can be disposed as a single layer, but is not limited thereto.

For example, the first substrate 110a and the second substrate 110b can be polyimide (PI) substrates and the interlayer insulating film 110c can be formed of a single layer of silicon nitride (SiNx) or silicon oxide (SiOx) or multiple layers thereof, but embodiments of the present disclosure are not limited thereto.

The interlayer insulating film 110c need not be disposed in at least a partial area. For example, the interlayer insulating film 110c can be not formed in an area to which a stress is concentrated, such as a bending area BA or an outermost area, but embodiments of the present disclosure are not limited thereto.

The light shielding layer LS can be disposed on the substrate 110. The light shielding layer LS can be a protection layer formed of metal which is disposed below semiconductor layers A1 and A2 of a plurality of transistors TR1 and RT2 to shield external light in the display apparatus 100. The light shielding layer LS can minimize damage of the semiconductor layers A1 and A2 which are caused by the external light.

The first buffer layer 111 can be disposed on the substrate 110 while covering the light shielding layer LS. Specifically, a multi-buffer layer 111a can be disposed on the substrate 110 while covering the light shielding layer LS and an active buffer layer 111b can be disposed on the multi-buffer layer 111a.

The multi-buffer layer 111a can delay diffusion of the moisture or oxygen permeating the substrate 110 and include at least any one of silicon nitride SiNx and silicon oxide SiOx.

The active buffer layer 111b can protect the first semiconductor layer A1 and block various types of defects introduced from the substrate 110. For example, the active buffer layer 111b can include at least any one of amorphous silicon (a-Si), silicon nitride SiNx, and silicon oxide SiOx, but embodiments of the present disclosure are not limited thereto.

The first thin film transistor TR1 can be disposed on the first buffer layer 111. The first thin film transistor TR1 can include the first semiconductor layer A1, a first gate electrode G1, a first source electrode S1, and a first drain electrode D1. Here, depending on the design of the pixel circuit, the first source electrode S1 can serve as a first drain electrode and the first drain electrode D1 can serve as a first source electrode.

The first semiconductor layer A1 can be disposed on the first buffer layer 111 so as to overlap the light shielding layer LS. The first semiconductor layer A1 can include amorphous silicon or polycrystalline silicon. For example, the first semiconductor layer A1 can include a low-temperature polycrystalline silicon LTPS. For example, the polycrystalline silicon material has a high mobility (100 cm²/Vs or higher) so that energy power consumption is low and reliability is excellent, but embodiments of the present disclosure are not limited thereto. Therefore, the polysilicon material can be applied to a gate driver for driving elements which drive thin film transistors for a display element and/or a multiplexer (MUX) and also applied as a first semiconductor layer A1 of a driving thin film transistor of the display apparatus 100 according to the example embodiment, but is not limited thereto. For example, the polycrystalline silicon material can also be applied as a second semiconductor layer A2 of the switching thin film transistor according to the characteristic of the display apparatus 100. An amorphous silicon (a-Si) material is deposited on the first buffer layer 111 and a dehydrogenation process and a crystallization process are performed to form polycrystalline silicon and the polycrystalline silicon is patterned to form the first semiconductor layer A1, but embodiments of the present disclosure are not limited thereto.

Here, the first semiconductor layer A1 can include a first channel region in which a channel is formed when the first thin film transistor TR1 is driven and a first source region and a first drain region on both sides of the first channel region. The first source region refers to a part of the first semiconductor layer A1 which is connected to the first source electrode S1 and the first drain region refers to a part of the first semiconductor layer A1 which is connected to the first drain electrode D1. For example, the first source region and the first drain region can be configured by ion-doping (impurity doping) of the first semiconductor layer A1. The first source region and the first drain region can be generated by doping ions into the polycrystalline silicon material and the first channel region can refer to a part which is not doped with ions, but remains as the polycrystalline silicon material, but embodiments of the present disclosure are not limited thereto.

The first gate insulating layer 112a can be disposed on the first semiconductor layer A1. The first gate insulating layer 112a can be configured by a single layer of silicon nitride (SiNx) or silicon oxide (SiOx) or a multi-layer thereof. In the first gate insulating layer 112a, a contact hole through which the first source electrode S1 and the first drain electrode D1 of the first thin film transistor TR1 are connected to the first source region and the first drain region of the first semiconductor layer A1 of the first thin film transistor TR1, respectively, can be formed.

The first gate electrode G1 of the first thin film transistor TR1 and a first capacitor electrode C1 of the storage capacitor Cst can be disposed on the first gate insulating layer 112a.

At this time, the first gate electrode G1 and the first capacitor electrode C1 can be formed by a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof. The first gate electrode G1 can be formed on the first gate insulating layer 112a so as to overlap the first channel region of the first semiconductor layer A1 of the first thin film transistor TR1.

The first capacitor electrode C1 can be omitted based on a driving characteristic of the display apparatus 100 and a structure and a type of the thin film transistor. The first gate electrode G1 and the first capacitor electrode C1 can be formed by the same process. Further, the first gate electrode G1 and the first capacitor electrode C1 can be formed of the same material on the same layer.

The first interlayer insulating layer 113a can be disposed above the first gate insulating layer 112a, the first gate electrode G1, and the first capacitor electrode C1. The first interlayer insulating layer 113a can be configured by a single layer of silicon nitride SiNx or silicon oxide SiOx or a multi-layer thereof. In the first interlayer insulating layer 113a, a contact hole for exposing the first source region and the first drain region of the first semiconductor layer A1 of the first thin film transistor TR1 can be formed.

A second capacitor electrode C2 of the storage capacitor Cst can be disposed on the first interlayer insulating layer 113a. The second capacitor electrode C2 can be formed by a single layer or multiple layers formed of any one of molybdenum (Mo), copper (Cu), titanium (Ti), aluminum (Al), chrome (Cr), gold (Au), nickel (Ni), and neodymium (Nd) or an alloy thereof. The second capacitor electrode C2 can be formed on the first interlayer insulating layer 113a so as to overlap the first capacitor electrode C1. Further, the second capacitor electrode C2 can be formed of the same material as the first capacitor electrode C1. The second capacitor electrode C2 can be omitted based on a driving characteristic of the display apparatus 100 and a structure and a type of the thin film transistor.

The second buffer layer 114 can be disposed on the first interlayer insulating layer 113a and the second capacitor electrode C2. The second buffer layer 114 can be configured by a single layer of silicon nitride (SiNx) or silicon oxide (SiOx) or a multi-layer thereof. A contact hole for exposing the first source region and the first drain region of the first semiconductor layer A1 of the first thin film transistor TR1 can be formed in the second buffer layer 114. Further, in the second buffer layer 114, a contact hole for exposing the second capacitor electrode C2 of the storage capacitor Cst can be formed.

The second buffer layer 114 can be formed by multiple layers, but is not limited thereto.

The second semiconductor layer A2 of the second thin film transistor TR2 can be disposed on the second buffer layer 114. Here, the second thin film transistor TR2 can include the second semiconductor layer A2, a second gate insulating layer 112b, a second gate electrode G2, a second source electrode S2, and a second drain electrode D2. Here, depending on the design of the pixel circuit, the second source electrode S2 can serve as a drain electrode and the second drain electrode D2 can serve as a source electrode.

Further, the second semiconductor layer A2 can include a second channel region in which a channel is formed when the second thin film transistor TR2 is driven and a second source region and a second drain region on both sides of the second channel region. The second source region can refer to a part of the second semiconductor layer A2 which is connected to the second source electrode S2 and the second drain region can refer to a part of the second semiconductor layer A2 which is connected to the second drain electrode D2.

The second semiconductor layer A2 can be formed of an oxide semiconductor. The oxide semiconductor material has a larger band gap than a silicon material so that electrons cannot jump over the band gap in an off state. Therefore, the oxide semiconductor material has a low off-current. Therefore, the thin film transistor including a semiconductor layer which is formed of an oxide semiconductor can be suitable for a switching thin film transistor which maintains on-time to be short and off-time to be long, but is not limited thereto.

Depending on the characteristic of the display apparatus 100, a thin film transistor including a semiconductor layer formed of oxide semiconductor can be applied as a driving thin film transistor. Further, due to the small off-current, a magnitude of an auxiliary capacitance can be reduced so that the oxide semiconductor can be appropriate for a high resolution display element. For example, the second semiconductor layer A2 can be formed of metal oxide and for example, can be formed of various metal oxides such as indium-gallium-zinc-oxide (IGZO). Here, the description was made under assumption that the second semiconductor layer A2 of the second thin film transistor TR2 is configured by IGZO, among various metal oxides, but it is not limited thereto. Therefore, the second semiconductor layer A2 can be formed of another metal oxide such as indium-zinc-oxide (IZO), indium-gallium-tin-oxide (IGTO), or indium-gallium-oxide (IGO), rather than IGZO.

The second semiconductor layer A2 can be formed by depositing the metal oxide on the second buffer layer 114, performing a heat treatment for stabilization, and then patterning the metal oxide.

The second gate insulating layer 112b can be disposed on the entire substrate 110 including the second semiconductor layer A2. For example, the second gate insulating layer 112b can be configured by a single layer of silicon nitride (SiNx) or silicon oxide (SiOx) or a multi-layer thereof, but embodiments of the present disclosure are not limited thereto.

The second gate electrode G2 can be disposed on the second gate insulating layer 112b.

The second gate electrode G2 can be formed by a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof.

For example, a metal material is formed on the second gate insulating layer 112b, a photoresist pattern is formed on the metal material, and then the metal material is wet-etched using the photoresist pattern as a mask to form the second gate electrode G2. As a wet etchant for etching the metal material, a material which selectively etches molybdenum (Mo), copper (Cu), titanium (Ti), aluminum (Al), chrome (Cr), gold (Au), nickel (Ni), and neodymium (Nd) or an alloy thereof which configures the metal material but does not etch the insulating material can be used, but embodiments of the present disclosure are not limited thereto.

The second interlayer insulating layer 113b can be disposed on the second gate insulating layer 112b and the second gate electrode G2. A contact hole for exposing the first semiconductor layer A1 of the first thin film transistor TR1 and the second semiconductor layer A2 of the second thin film transistor TR2 can be formed in the second interlayer insulating layer 113b. For example, a contact hole for exposing the first source region and the first drain region of the first semiconductor layer A1 of the first thin film transistor TR1 can be formed in the second interlayer insulating layer 113b. A contact hole for exposing the second source region and the second drain region of the second semiconductor layer A2 of the second thin film transistor TR2 can be formed in the second interlayer insulating layer 113b, but embodiments of the present disclosure are not limited thereto.

The second interlayer insulating layer 113b can be configured as a single layer of silicon nitride SiNx or silicon oxide SiOx or a multi-layer thereof.

The connection electrode CE, the first source electrode S1 and the first drain electrode D1 of the first thin film transistor TR1 and the second source electrode S2 and the second drain electrode D2 of the second thin film transistor TR2 can be disposed on the second interlayer insulating layer 113b.

The connection electrode CE can be electrically connected to the second drain electrode D2 of the second thin film transistor TR2. Further, the connection electrode CE can be electrically connected to the second capacitor electrode C2 of the storage capacitor Cst through the contact holes formed in the second buffer layer 114 and the second interlayer insulating layer 113b. For example, the connection electrode CE can serve to electrically connect the second capacitor electrode C2 of the storage capacitor Cst and the second drain electrode D2 of the second thin film transistor TR2 to each other, but embodiments of the present disclosure are not limited thereto.

Here, the first source electrode S1 and the first drain electrode D1 of the first thin film transistor TR1 can be connected to the first semiconductor layer A1 of the first thin film transistor TR1 through the contact holes formed in the first gate insulating layer 112a, the first interlayer insulating layer 113a, the second buffer layer 114, and the second interlayer insulating layer 113b.

The second source electrode S2 and the second drain electrode D2 of the second thin film transistor TR2 can be connected to the second semiconductor layer A2 through the contact hole formed in the second gate insulating layer 112b.

The connection electrode CE, the first source electrode S1 and the first drain electrode D1 of the first thin film transistor TR1 and the second source electrode S2 and the second drain electrode D2 of the second thin film transistor TR2 can be formed of the same material by the same process.

For example, the connection electrode CE, the first source electrode S1 and the first drain electrode D1 of the first thin film transistor TR1 and the second source electrode S2 and the second drain electrode D2 of the second thin film transistor TR2 can be formed by a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof, but embodiments of the present disclosure are not limited thereto. For example, the connection electrode CE, the first source electrode S1 and the first drain electrode D1 of the first thin film transistor TR1 and the second source electrode S2 and the second drain electrode D2 of the second thin film transistor TR2 can be formed of a triple-layered structure of titanium (Ti)/aluminum (Al)/titanium (Ti), but are not limited thereto.

The connection electrode CE can be integrally formed to be connected to the second drain electrode D2 of the second thin film transistor TR2, but is not limited thereto.

The first planarization layer 115a can be disposed on the connection electrode CE, the first source electrode S1 and the first drain electrode D1 of the first thin film transistor TR1, the second source electrode S2 and the second drain electrode D2 of the second thin film transistor TR2, and the second interlayer insulating layer 113b.

The first planarization layer 115a can be an organic layer which planarizes and protects upper portions of the first thin film transistor TR1 and the second thin film transistor TR2. For example, the first planarization layer 115a can be formed of an organic material such as acryl resin, epoxy resin, phenolic resin, polyamide resin, or polyimide resin, but embodiments of the present disclosure are not limited thereto.

The auxiliary electrode AE can be disposed on the first planarization layer 115a. The auxiliary electrode AE can be connected to the second drain electrode D2 of the second thin film transistor TR2 through the contact hole of the first planarization layer 115a. The auxiliary electrode AE can serve to electrically connect the second thin film transistor TR2 and the anode 121 with each other. The auxiliary electrode AE can be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof. The auxiliary electrode AE can be formed of the same material as the second source electrode S2 and the second drain electrode D2 of the second thin film transistor TR2.

The second planarization layer 115b can be disposed above the auxiliary electrode AE and the first planarization layer 115a. For example, the second planarization layer 115b can be formed of an organic material, such as acryl resin, epoxy resin, phenolic resin, polyamide resin, or polyimide resin, but embodiments of the present disclosure are not limited thereto.

The light emitting diode 120 can be disposed on the second planarization layer 115b. The light emitting diode 120 includes an anode 121, an emission layer 122, and a cathode 123.

The anode 121 can be disposed on the second planarization layer 115b. At this time, the anode 121 can be electrically connected to the auxiliary electrode AE through the contact hole provided in the second planarization layer 115b. The anode 121 can be formed of a metallic material.

When the display apparatus 100 is a top emission type in which light emitted from the light emitting diode 120 is emitted above the substrate 110 on which the light emitting diode 120 is disposed, the anode 121 can include a reflective layer and a transparent conductive layer disposed on the reflective layer. The transparent conductive layer can be formed of transparent conductive oxide such as indium tin oxide (ITO) or indium zinc oxide (IZO) and the reflective layer can be formed of silver (Ag), aluminum (Al), gold (Au), molybdenum (Mo), tungsten (W), chrome (Cr), or an alloy thereof, but they are not limited thereto.

The bank unit 116 is disposed on the anode 121. The bank unit 116 includes a bank 116a and a spacer 116b.

The bank 116a can be disposed while covering an end of the anode 121. A part of the bank 116a corresponding to an emission area of the sub pixel can be open. A part of the anode 121 can be exposed through the open part of the bank 116a (hereinafter, referred to as an open area). At this time, the bank 116a can be formed of an inorganic insulating material, such as silicon nitride (SiNx) or silicon oxide (SiOx), or an organic insulating material, such as benzocyclobutene resin, acrylic resin or imide resin, but is not limited thereto.

The spacer 116b can be further disposed on the bank 116a. The spacer 116b can serve to maintain a predetermined gap so as not to allow a mask to be in contact with a substrate during a manufacturing process of an emission layer 122 of the light emitting diode 120 which is formed of an organic material.

For example, the spacer 116b can be formed of an inorganic insulating material, such as silicon nitride (SiNx) or silicon oxide (SiOx), or an organic insulating material, such as benzocyclobutene resin, acrylic resin or imide resin, but is not limited thereto.

The emission layer 122 is disposed on the anode 121, the bank 116a, and the spacer 116b. The emission layer 122 can be disposed in the open area of the bank 116a and in the vicinity of the open area of the bank. Therefore, the emission layer 122 can be disposed on the anode 121 exposed through the open area of the bank 116a.

The emission layer 122 can include a plurality of organic material layers. For example, the emission layer 122 can include an organic material layer such as a hole injection layer, a hole transport layer, an electron transport layer, and an electron injection layer, but embodiments of the present disclosure are not limited thereto. In the meantime, when the emission layer 122 emits white light, light emitted from the emission layer 122 can be converted into light with various colors by a plurality of color filters CF, but is not limited thereto.

The cathode 123 is disposed on the emission layer 122. The cathode 123 supplies electrons to the emission layer 122 so that the cathode can be formed of a conductive material having a low work function. The cathode 123 can be formed as one layer over the plurality of sub pixels SP. For example, the cathodes 123 of the plurality of sub pixels SP can be connected to be integrally formed.

For example, the cathode 123 can be formed of a transparent conductive material such as indium tin oxide (ITO) and indium zinc oxide (IZO) or ytterbium (Yb) alloy and can further include a metal doping layer, but is not limited thereto.

The encapsulation unit 117 is disposed on the light emitting diode 120.

The encapsulation unit 117 can have a single layer structure or a multi-layered structure. For example, the encapsulation unit 117 can have a multi-layered structure including a first encapsulation layer 117a, a second encapsulation layer 117b, and a third encapsulation layer 117c. However, the encapsulation unit can also be formed with a single layer structure, but is not limited thereto.

The first encapsulation layer 117a and the third encapsulation layer 117c can be formed of inorganic materials and the second encapsulation layer 117b can be formed of an organic material. The second encapsulation layer 117b can be the thickest among the first encapsulation layer 117a, the second encapsulation layer 117b, and the third encapsulation layer 117c. The second encapsulation layer 117b can planarize an upper portion of the light emitting diode 120.

The first encapsulation layer 117a can be disposed on the cathode 123 and be disposed to be most adjacent to the light emitting diode 120, in the encapsulation unit 117. For example, the first encapsulation layer 117a can be configured by silicon nitride SiNx, silicon oxide (SiOx), silicon oxynitride (SiON), or aluminum oxide (Al₂O₃), but is not limited thereto.

The second encapsulation layer 117b can be formed to have a smaller area than that of the first encapsulation layer 117a. In this case, the second encapsulation layer 117b can be formed to expose both ends of the first encapsulation layer 117a. The second encapsulation layer 117b can serve to enhance a buffering function to alleviate stress between the layers due to bending of the flexible display apparatus and a planarization function.

For example, the second encapsulation layer 117b can be formed of an organic insulating material, such as acrylic resin, epoxy resin, polyimide, polyethylene, or silicon oxy carbon (SiOC), but embodiments of the present disclosure are not limited thereto. For example, the second encapsulation layer 117b can be formed by an inkjet method, but is not limited thereto.

The third encapsulation layer 117c can be formed above the substrate 110 on which the second encapsulation layer 117b is formed so as to cover upper surfaces and side surfaces of the second encapsulation layer 117b and the first encapsulation layer 117a. At this time, the third encapsulation layer 117c can minimize or block the permeation of external moisture or oxygen into the first encapsulation layer 117a and the second encapsulation layer 117b. For example, the third encapsulation layer 117c can be configured by an inorganic insulating material, such as silicon nitride SiNx, silicon oxide SiOx, silicon oxynitride SiON, or aluminum oxide Al₂O₃, but can be not limited thereto.

The touch sensing unit can be disposed on the encapsulation unit 117.

The touch sensing unit can include the touch buffer layer 118a, the touch interlayer insulating layer 118b, the touch electrode TE, the third planarization layer 118c, and a touch routing line TL. The touch electrode TE can include a touch sensor electrode TS and a touch bridge electrode TB located on different layers.

For example, the touch buffer layer 118a can be disposed above the third encapsulation layer 117c and the touch bridge electrode TB can be disposed on the touch buffer layer 118a.

The touch interlayer insulating layer 118b can be disposed on the touch bridge electrode TB and the touch sensor electrode TS can be disposed on the touch interlayer insulating layer 118b.

The third planarization layer 118c is disposed on the touch sensor electrode TS. The third planarization layer 118c can be an organic layer which planarizes and protects an upper portion of the touch sensor electrode TS. Therefore, the third planarization layer 118c can be disposed to be in contact with the touch sensor electrode TS. For example, the third planarization layer can be formed of an organic material such as acryl resin, epoxy resin, phenolic resin, polyamide resin, or polyimide resin, but is not limited thereto. For example, the touch buffer layer 118a, the touch interlayer insulating layer 118b, and the third planarization layer 118c can be formed of an inorganic insulating material or an organic insulating material. Therefore, the touch buffer layer 118a, the touch interlayer insulating layer 118b, and the third planarization layer 118c can minimize a step in a location where the touch electrode TE is disposed and electrically insulate the touch sensor electrode TS from the touch bridge electrode TB.

The fourth planarization layer 119 is disposed on the third planarization layer 118c. The fourth planarization layer 119 can planarize upper portions of the plurality of touch electrodes TE. Specifically, the fourth planarization layer 119 can be configured to entirely planarize upper portions of the active area AA, the first non-active area NA1, and the second non-active area NA2 on the substrate 110. Therefore, the fourth planarization layer 119 can be a configuration which is disposed on the uppermost layer in the substrate 110, but is not limited thereto. The fourth planarization layer 119 can be formed of an organic material, such as epoxy-based resin, but is not limited thereto.

Hereinafter, a cross-sectional structure of the first non-active area NA1 adjacent to the bending area BA will be described with reference to FIGS. 3A to 7 together.

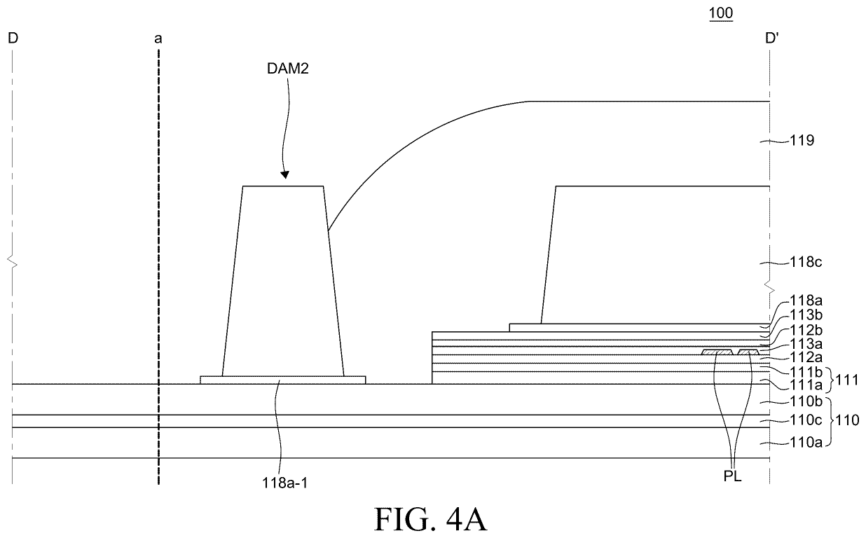

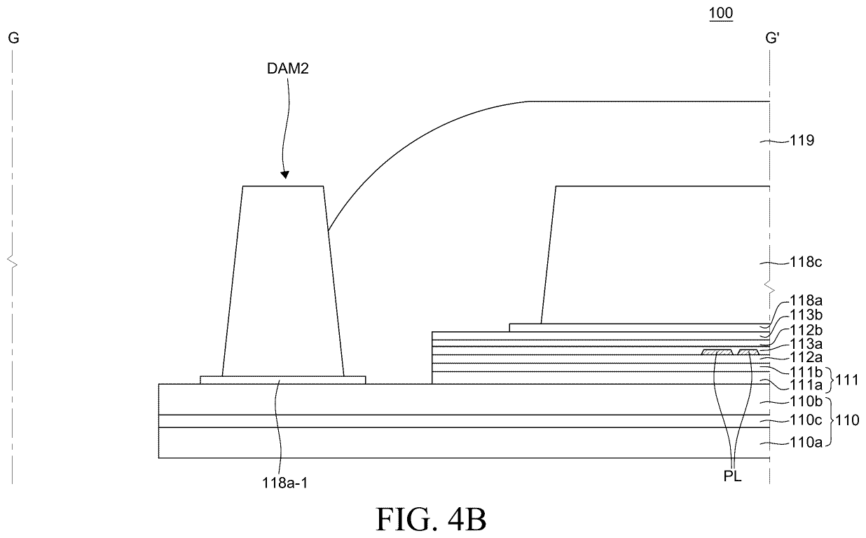

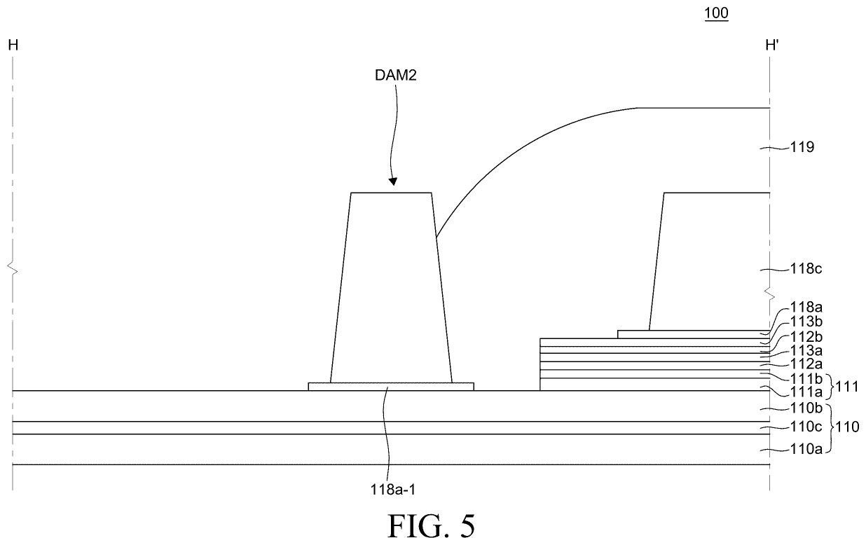

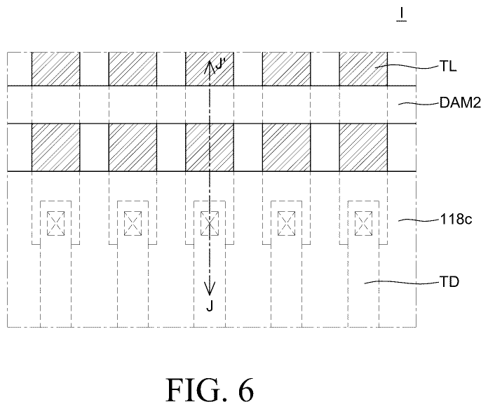

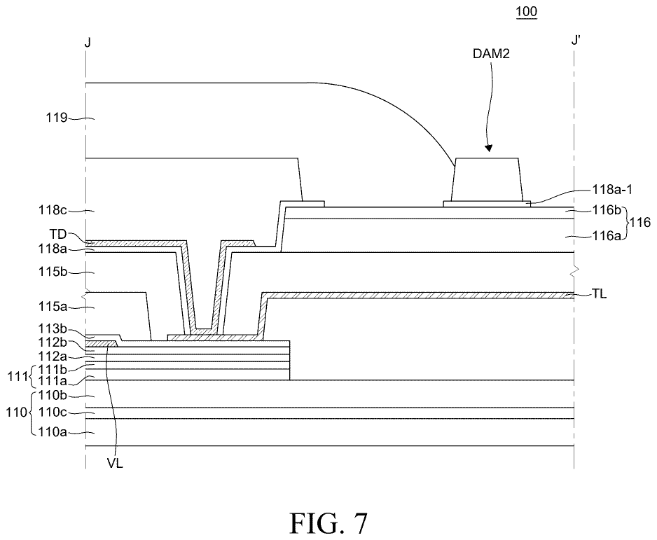

FIG. 3A is a cross-sectional view taken along C-C′ of FIG. 1B. FIG. 3B is a cross-sectional view taken along F-F′ of FIG. 1D. FIG. 4A is a cross-sectional view taken along D-D′ of FIG. 1B. FIG. 4B is a cross-sectional view taken along G-G′ of FIG. 1D. FIG. 5 is a cross-sectional view taken along H-H′ of FIG. 1D. FIG. 6 is an enlarged plan view of an area I of FIG. 1A. FIG. 7 is a cross-sectional view taken along J-J′ of FIG. 6. FIGS. 3A to 7 are cross-sectional views and plan views of each area of the first non-active area NA1 according to an example embodiment of the present disclosure. FIGS. 3A and 3B are cross-sectional views illustrating the same area and FIGS. 4A and 4B are cross-sectional views illustrating the same area. FIGS. 3A and 4A are cross-sectional views before the trimming process and FIGS. 3B and 4B are cross-sectional views after the trimming process.

Referring to FIGS. 3A to 7, in the display apparatus 100 according to the example embodiment of the present disclosure, in the first non-active area NA1 of the substrate 110, a power line PL, a first dam DAM1, a second dam DAM2, a third planarization layer 118c, and a fourth planarization layer 119 are disposed.

In the first non-active area NA1, the power line PL can be disposed on the second interlayer insulating layer 113b. For example, a low potential voltage or a high potential voltage can be supplied to the sub pixel SP of the display apparatus 100 through the power line PL. At this time, the power line PL can be formed on the same layer as the first gate electrode G1 disposed in the active area AA with the same material, but is not limited thereto.

In the meantime, referring to FIGS. 3A and 3B, the power line PL can include a plurality of holes. Therefore, gas which is generated from the first gate insulating layer 112a or the first interlayer insulating layer 113a during the manufacturing process can be easily discharged to the outside through the plurality of holes of the power line PL.

Referring to FIGS. 3A and 3B, in the first non-active area NA1, a plurality of dams is disposed in an area adjacent to an end of the substrate 110. Each of the plurality of dams is disposed so as to enclose the active area AA in the first non-active area NA1.

The plurality of dams can include a first dam DAM1 and a second dam DAM2.

The plurality of first dams DAM1 is disposed to be adjacent to the active area AA to suppress excessive application of the second encapsulation layer 117b.

The first dam DAM1 illustrated in FIGS. 3A and 3B can be the outermost dam which is disposed in the outermost periphery of the substrate 110, among the plurality of first dams DAM1. Hereinafter, the first dam DAM1 can cover ends of the plurality of inorganic insulating layers disposed in the first non-active area NA1, but is not limited thereto.

The plurality of first dams DAM1 can have a structure in which a plurality of organic layers formed by the same material as components disposed in the active area AA is laminated. For example, each of the plurality of first dams DAM1 can be formed with the same material by the same process as the second planarization layer 115b and the bank 116a and can be formed by the same process as the spacer 116b, but is not limited thereto.

Further, even though in FIGS. 3A and 3B, it is illustrated that the plurality of first dams DAM1 is configured by one, it is not limited thereto and the number of the plurality of dams can be changed if necessary.

Referring to FIGS. 3A, 4A, 4B and 5, the first dam DAM1 can be disposed to cover or partially cover ends of one or more of the plurality of inorganic insulating layers, such as the first buffer layer 111, the first and second gate insulating layers 112a and 112b, the first and second interlayer insulating layers 113a and 113b, the touch buffer layer 118a, or others. For example, a first side of the first dam DAM1 can be located on a surface of one of the plurality of inorganic insulating layers, such as the touch buffer layer 118a and a second side of the first dam DAM1 can be located on a surface of the second substrate 110b, for example, but embodiments of the present disclosure are not limited thereto. In other embodiments of the present disclosure, an outermost first DAM1 need not be located along an edge of the first non-active area NA1 that abuts the bending area BA along a periphery of the active area AA. In such an instance of the embodiment of the present disclosure, the first dam DAM1 can be located along the edges of the non-active area NA1 in opposite lateral sides (i.e., left and right sides) and the lower side of the first non-active area NA1 and not located on the upper side of the first non-active area NA1 (see FIGS. 1A and 1B). In such an instance, the upper side of the first non-active area NA1 can have the second dam DAM2 and not the first dam DAM1, but embodiments of the present disclosure are not limited thereto. In other embodiments of the present disclosure, the outermost first DAM1 can also be located on the upper side of the first non-active area NA1 that abuts the bending area BA along the periphery of the active area AA, in addition to the opposite lateral sides (i.e., left and right sides) and the lower side of the first non-active area NA1.

Referring to FIGS. 3A, 4A, 4B, and 5, the second dam DAM2 is disposed to be adjacent to the bending area BA in the first non-active area NA1. For example, the second dam DAM2 can be formed on the same layer with the same material as the third planarization layer 118c. An end of the fourth planarization layer 119 can be disposed inside the second dam DAM2. The fourth planarization layer 119 can be filled in a space between the first dam DAM1 and the second dam DAM2. The second dam DAM2 can be configured to be disposed to be adjacent to the bending area BA in the first non-active area NA1 to minimize excessive application of the fourth planarization layer 119. Therefore, the second dam DAM2 can minimize erroneous operations of components disposed in the bending area BA and the second non-active area NA2 due to the fourth planarization layer 119.

Further, referring to FIGS. 3A and 3B, an end of the third planarization layer 118c can be disposed more inward in location than a location of the first dam DAM1. The fourth planarization layer 119 can also be filled in a space between the end of the third planarization layer 118c and the first dam DAM1.

At this time, referring to FIGS. 3A, 4A, 4B, and 5, the second dam DAM2 can be disposed to be spaced apart from the plurality of inorganic insulating layers whose ends are covered by the first dam DAM1 in the first non-active area NA1. For example, the plurality of inorganic insulating layers can be not disposed below the second dam DAM2. At this time, the fourth planarization layer 119 can be further filled in a space between the first dam DAM1 and the second dam DAM2 as much as a space from which the inorganic insulating layer is removed.

With reference to FIGS. 3A, 4A, 4B, 5, and 7, a height of the second dam DAM2 can be about the same or the same as a height of the third planarization layer 118c, but embodiments of the present disclosure as not limited thereto. For example, the height of the second dam DAM2 can be different from the height of the third planarization layer 118c. Also, a height of the first dam DAM1 can have a height that is different from the height of the second dam DAM2 and/or the height of the third planarization layer 118c. For example, the height of the first dam DAM1 can be less than at least one of the height of the second dam DAM2 and the height of the third planarization layer 118c, but embodiments of the present disclosure are not limited thereto, and the height of the first dam DAM1 can be the same or greater than the at least one of the height of the second dam DAM2 and the height of the third planarization layer 118c.

In the meantime, referring to FIGS. 3A, 4A, 4B, 5, and 7, an additional inorganic layer 118a-1 can be disposed below the second dam DAM2. The additional inorganic layer 118a-1 can be formed with the same material on the same layer as the touch buffer layer 118a. For example, the additional inorganic layer 118a-1 can be deposited on the same layer by the same process as the touch buffer layer 118a, and then can be etched to be formed together with the second dam DAM2 in the process of forming the second dam DAM2, but is not limited thereto.

The additional inorganic layer 118a-1 can be disposed to improve the adhesive strength to the second dam DAM2. For example, the additional inorganic layer 118a-1 can improve the adhesive strength between the substrate 110 or the bank unit 116 and the second dam DAM2 to minimize a deviation of the second dam DAM2, but is not limited thereto.

In the meantime, referring to FIGS. 3A to 5, in the first non-active area NA1 adjacent to the bending area BA, the fourth planarization layer 119 can have different cross-sections in an area in which the second dam DAM2 is disposed and an area in which the second dam DAM2 is not disposed. For example, as illustrated in FIGS. 3A and 3B, in the first non-active area NA1 adjacent to the bending area BA, in an area from which the second dam DAM2 is removed by the trimming process, an end of the fourth planarization layer 119 can be disposed on the same plane as the end of the substrate 110. Further, the thickness of the fourth planarization layer 119 can become smaller toward an end of the fourth planarization layer 119. As illustrated in FIGS. 4A, 4B, and 5, in the first non-active area NA1 adjacent to the bending area BA, in an area from which the second dam DAM2 is not removed by the trimming process, an end of the fourth planarization layer 119 can be disposed more inward than the end of the substrate 110.

With reference to FIGS. 3A to 5, an area of layers located outward of the ends of the plurality of inorganic insulating layers disposed in the first non-active area NA1 can be exposed. For example, in the area of the entire substrate 110 that is outward of the ends of the plurality of inorganic insulating layers disposed in the first non-active area NA1 can be exposed. In the embodiments shown in FIGS. 3A to 5, an upper surface of the second substrate 110b is exposed between the ends of the plurality of inorganic insulating layers and the second dam DAM2 or a trimmed end of the entire substrate 110 at the predetermined trimming line a, but is not limited thereto, and an upper surface of the first substrate 110a or the interlayer insulating film 110c can be a portion that is exposed.

In various embodiments of the present disclosure, the exposed portion of the entire substrate 110 between the ends of the plurality of inorganic insulating layers and the second dam DAM2 can be a groove or a recess to receive the fourth planarization layer 119, and a depth of the groove or the recess in the exposed portion of the entire substrate 110 can vary between a floor of the exposed portion the entire substrate 110 to an upper surface of the fourth planarization layer 119 that overlaps the exposed portion of the entire substrate 110. In this regard, an uppermost surface of the second dam DAM2 can be higher in height than the end of the upper surface of the fourth planarization layer 119 that contacts the second dam DAM2, and an uppermost surface of the first dam DAM1 can be lower in height than the upper surface of the fourth planarization layer 119 that overlaps the exposed portion of the entire substrate 110.

Referring to FIGS. 6 and 7, the touch sensing unit further includes a plurality of touch sensing lines TD and a plurality of touch routing line TL disposed in the first non-active area NA1.

The plurality of touch sensing lines TD is connected to the plurality of touch electrodes TE disposed in the active area AA and extends to the first non-active area NA1 adjacent to the bending area BA. For example, the plurality of touch sensing lines TD can be formed with the same material on the same layer as the touch sensor electrode TS disposed in the active area AA, but is not limited thereto.

The plurality of touch routing lines TL can extend to the first non-active area NA1, the bending area BA, and the second non-active area NA2. The plurality of touch routing lines TL can be connected to the plurality of touch sensing lines TD in the first non-active area NA1, respectively. For example, the plurality of touch routing lines TL can be formed with the same material on the same layer as the auxiliary electrode AE disposed in the active area AA, but is not limited thereto.

The plurality of touch sensing lines TD and the plurality of touch routing lines TL, for example, can be configured to transmit and receive a touch sensing signal to and from a touch driving circuit which controls the touch sensing unit.

In the meantime, referring to FIGS. 6 and 7, the plurality of touch routing lines TL can be disposed so as to overlap the second dam DAM2. For example, the second dam DAM2 can be disposed so as to overlap the plurality of touch routing lines TL in the first non-active area NA1 adjacent to the bending area BA. At this time, the fourth planarization layer 119 can be filled in a space between the end of the third planarization layer 118c and the second dam DAM2.

At this time, referring to FIG. 7, the third planarization layer 118c is disposed in an area adjacent to the plurality of touch routing lines TL so as to expose an end of the touch buffer layer 118a. For example, in an area adjacent to the plurality of touch routing lines TL, the third planarization layer 118c can be partially removed to an area which exposes an end of the touch buffer layer 118a. Accordingly, a space between the end of the third planarization layer 118c and the second dam DAM2 can be further expanded and the fourth planarization layer 119 can be filled more in the space between the end of the third planarization layer 118c and the second dam DAM2.

In the meantime, referring to FIG. 7, various wiring lines VL can be further disposed in the first non-active area NA1 adjacent to the plurality of touch routing lines TL. The wiring line VL can be disposed inside more than the ends of the plurality of touch sensing lines TD. For example, the wiring line VL can be a power line which supplies a low potential voltage or a high potential voltage to the sub pixel SP. The wiring line VL can be formed with the same material on the same layer as the source electrodes S1 and S2 and the drain electrodes D1 and D2 disposed in the active area AA, but is not limited thereto.

In the display apparatus, a through hole which is formed so as to correspond to the camera or the photo sensor can be disposed in the active area. At this time, as the camera or the photo sensor is disposed in the through hole, an additional planarization layer can be disposed, in addition to the component, such as an encapsulation layer, so as to planarize an upper portion thereof. However, when the additional planarization layer is disposed, in the non-active area, the added planarization layer can be excessively applied in an area in which the plurality of pads or driving ICs is disposed, which causes erroneous operations of the plurality of pads or driving ICs.

In the display apparatus 100 according to the example embodiment of the present disclosure, the second dam DAM2 is disposed in an area of the first non-active area NA1 adjacent to the bending area BA to minimize excessive application of the fourth planarization layer 119.

In the display apparatus 100 according to the example embodiment of the present disclosure, in the first non-active area NA1, the second dam DAM2 is disposed in an area adjacent to the bending area BA. The second dam DAM2 can be formed with the same material on the same layer as the third planarization layer 118c which planarizes an upper portion of the plurality of touch electrodes TE. Therefore, the second dam DAM2 can be formed above the touch routing line TL disposed in the first non-active area NA1 adjacent to the bending area BA. Accordingly, the second dam DAM2 can be configured to minimize excessive application of the fourth planarization layer which is disposed on the uppermost layer on the substrate 110. In the display apparatus 100 according to the example embodiment of the present disclosure, the second dam DAM2 is disposed in an area of the first non-active area NA1 adjacent to the bending area BA to minimize excessive application of the fourth planarization layer 119. Further, the reliability of the display apparatus can be improved.

The example embodiments of the present disclosure can also be described as follows:

According to an aspect of the present disclosure, a display apparatus includes a substrate which includes an active area, a first non-active area enclosing the active area, a bending area extending from the first non-active area to be bent, and a second non-active area extending from the bending area; a plurality of light emitting diodes disposed on the substrate in the active area; a touch sensing unit disposed above the plurality of light emitting diodes; a first planarization layer disposed on the touch sensing unit; a first dam which is disposed in the non-active area so as to enclose the active area; a second planarization layer which is disposed on the first dam and the first planarization layer; and a second dam which is disposed along a boundary of the first non-active area and the bending area, in the first non-active area, in which the second dam is formed with the same material on the same layer as the first planarization layer.

An end of the second planarization layer can be disposed inside the second dam.

In the first non-active area adjacent to the bending area in which the second dam is not disposed, an end of the second planarization layer can be disposed on the same plane as an end of the substrate.

In the first non-active area in which the second dam is not disposed, a thickness of the second planarization layer can become smaller toward the end of the second planarization layer.

The display apparatus can further comprise an encapsulation layer disposed between the plurality of light emitting diodes and the touch sensing unit, a touch buffer layer disposed between the encapsulation layer and the touch sensing unit, and an additional inorganic layer which is disposed below the second dam and is formed with the same material on the same layer as the touch buffer layer.

The touch sensing unit can include a plurality of touch electrodes disposed in the active area, a plurality of touch sensing lines which extends from the plurality of touch electrodes to the first non-active area adjacent to the bending area, and a plurality of touch routing lines which is connected to the plurality of touch sensing lines in the first non-active area and extends to the bending area and the second non-active area.

The plurality of touch routing lines can be disposed so as to overlap the second dam.

In an area adjacent to the plurality of touch routing lines, the first planarization layer can be disposed so as to cover an end of the touch sensing line and exposes an end of the touch buffer layer.

The second planarization layer can be filled in a space between an end of the first planarization layer and the second dam.

The display apparatus can further comprise a plurality of inorganic insulating layers disposed between the substrate and the plurality of light emitting diodes.

In the first non-active area, the plurality of inorganic insulating layers can be disposed inside more than the second dam and is spaced apart from the second dam.

In the first non-active area, ends of the plurality of inorganic insulating layers can be covered by the first dam and the second planarization layer can be disposed in a space between the first dam and the second dam.

An end of the first planarization layer can be disposed inside more than the first dam and the second planarization layer can be also filled in a space between the end of the first planarization layer and the first dam.

According to another aspect of the present disclosure, a display apparatus includes: a substrate which includes an active area in which a plurality of sub pixels is disposed, a first non-active area enclosing the active area, and a bending area extending from the first non-active area to be bent; a plurality of light emitting diodes which is disposed in each of the plurality of sub pixels on the substrate; a touch sensing unit disposed above the plurality of light emitting diodes; a first planarization layer disposed on the touch sensing unit; a first dam which is disposed in the non-active area so as to enclose the active area; a second planarization layer which is disposed on the first dam and the first planarization layer; and a second dam which is disposed along a boundary of the first non-active area and the bending area, in the first non-active area, in which the second dam is disposed on the same layer as the first planarization layer and is formed with the same material as the first planarization layer.

An end of the second planarization layer can be disposed inside the second dam.

In the first non-active area adjacent to the bending area in which the second dam is not disposed, a thickness of the second planarization layer can become smaller toward an end of the second planarization layer.

In the first non-active area in which the second dam is not disposed, the end of the second planarization layer can be disposed on the same plane as an end of the substrate.

The display apparatus can further comprise an encapsulation layer disposed between the plurality of light emitting diodes and the touch sensing unit, a touch buffer layer disposed between the encapsulation layer and the touch sensing unit, and an additional inorganic layer which is disposed below the second dam and is formed with the same material on the same layer as the touch buffer layer.

The substrate can further include a second non-active area extending from the bending area.

The touch sensing unit can include a plurality of touch electrode disposed in the active area, and a plurality of touch routing lines which is electrically connected to the plurality of touch electrodes and extends to the bending area and the second non-active area in the first non-active area.

The plurality of touch routing lines can be disposed so as to overlap the second dam and in an area adjacent to the plurality of touch routing lines, the first planarization layer can be disposed so as to expose an end of the touch buffer layer.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display apparatus, comprising:
a substrate including an active area, a first non-active area enclosing the active area, a bending area extending from the first non-active area and configured to be bent, and a second non-active area extending from the bending area;
a plurality of light emitting diodes disposed in the active area on the substrate;
a touch sensing unit disposed above the plurality of light emitting diodes;
a first planarization layer disposed on the touch sensing unit;
a first dam disposed in the first non-active area so as to enclose the active area;
a second planarization layer disposed on the first dam and the first planarization layer; and
a second dam disposed along a boundary of the first non-active area and the bending area, in the first non-active area,
wherein the second dam includes a same material on a same layer as the first planarization layer.

2. The display apparatus according to claim 1, wherein an end of the second planarization layer is disposed inside the second dam.

3. The display apparatus according to claim 1, wherein in the first non-active area adjacent to the bending area in which the second dam is not disposed, an end of the second planarization layer is disposed on a same plane as an end of the substrate.

4. The display apparatus according to claim 3, wherein in the first non-active area in which the second dam is not disposed, a thickness of the second planarization layer becomes smaller toward the end of the second planarization layer.

5. The display apparatus according to claim 1, further comprising:
an encapsulation layer disposed between the plurality of light emitting diodes and the touch sensing unit;
a touch buffer layer disposed between the encapsulation layer and the touch sensing unit; and
an additional inorganic layer disposed below the second dam and includes a same material on a same layer as the touch buffer layer.

6. The display apparatus according to claim 5, wherein the touch sensing unit includes:
a plurality of touch electrodes disposed in the active area;
a plurality of touch sensing lines which extends from the plurality of touch electrodes to the first non-active area adjacent to the bending area; and
a plurality of touch routing lines connected to the plurality of touch sensing lines in the first non-active area and extends to the bending area and the second non-active area, and
wherein the plurality of touch routing lines is disposed so as to overlap the second dam.

7. The display apparatus according to claim 6, wherein in an area adjacent to the plurality of touch routing lines, the first planarization layer is disposed so as to cover an end of a touch sensing line of the plurality of touch sensing lines and exposes an end of the touch buffer layer.

8. The display apparatus according to claim 7, wherein the second planarization layer is filled in a space between an end of the first planarization layer and the second dam.

9. The display apparatus according to claim 1, further comprising:
a plurality of inorganic insulating layers disposed between the substrate and the plurality of light emitting diodes,
wherein in the first non-active area, the plurality of inorganic insulating layers is disposed inside more than the second dam and is spaced apart from the second dam.

10. The display apparatus according to claim 9, wherein in the first non-active area, ends of the plurality of inorganic insulating layers are covered by the first dam and the second planarization layer is disposed in a space between the first dam and the second dam.

11. The display apparatus according to claim 10, wherein an end of the first planarization layer is disposed more inward than the first dam and the second planarization layer is also filled in a space between the end of the first planarization layer and the first dam.

12. A display apparatus, comprising:
a substrate including an active area in which a plurality of sub pixels is disposed, a first non-active area enclosing the active area, and a bending area extending from the first non-active area to be bent;
a plurality of light emitting diodes disposed in each of the plurality of sub pixels on the substrate;
a touch sensing unit disposed above the plurality of light emitting diodes;
a first planarization layer disposed on the touch sensing unit;
a first dam disposed in the first non-active area so as to enclose the active area;
a second planarization layer disposed on the first dam and the first planarization layer; and
a second dam disposed along a boundary of the first non-active area and the bending area, in the first non-active area,
wherein the second dam is disposed on a same layer as the first planarization layer and includes a same material as the first planarization layer.

13. The display apparatus according to claim 12, wherein an end of the second planarization layer is disposed inside the second dam.

14. The display apparatus according to claim 12, wherein in the first non-active area adjacent to the bending area in which the second dam is not disposed, a thickness of the second planarization layer becomes smaller toward an end of the second planarization layer.

15. The display apparatus according to claim 14, wherein in the first non-active area in which the second dam is not disposed, the end of the second planarization layer is disposed on a same plane as an end of the substrate.

16. The display apparatus according to claim 12, further comprising:
an encapsulation layer disposed between the plurality of light emitting diodes and the touch sensing unit;
a touch buffer layer disposed between the encapsulation layer and the touch sensing unit; and
an additional inorganic layer disposed below the second dam and includes a same material on a same layer as the touch buffer layer.

17. The display apparatus according to claim 16, wherein the substrate further includes a second non-active area extending from the bending area,
wherein the touch sensing unit includes:
a plurality of touch electrodes disposed in the active area; and
a plurality of touch routing lines which is electrically connected to the plurality of touch electrodes and extend to the bending area and the second non-active area in the first non-active area, and
wherein the plurality of touch routing lines is disposed so as to overlap the second dam and in an area adjacent to the plurality of touch routing lines, the first planarization layer is disposed so as to expose an end of the touch buffer layer.

18. A display apparatus, comprising:
a substrate including an active area, a first non-active area adjacent to the active area, a bending area extending from the first non-active area and configured to be bent, and a second non-active area extending from the bending area;
a plurality of light emitting diodes disposed in the active area on the substrate;
a planarization layer disposed on the plurality of light emitting diodes and having a first height; and
a dam disposed along a boundary of the first non-active area and the bending area, and located in the first non-active area,
wherein the dam includes a same material as the planarization layer and has a second height that is approximately equal to the first height.

19. The display apparatus according to claim 18, further comprising another planarization layer disposed on the planarization layer,
wherein the dam blocks the another planarization layer from overflowing from the active area into the bending area.

20. The display apparatus according to claim 19, wherein an upper surface of the substrate is exposed to the another planarization layer and contacts the another planarization layer.
